(19) United States
(12) Patent Application Publication
(10) Pub. No.: US 2024/0341154 A1
(43) Pub. Date: Oct. 10, 2024

(54) DISPLAY DEVICE INCLUDING A PROTECTIVE WELDING AND METHOD OF MANUFACTURING THE SAME

(71) Applicant: SAMSUNG DISPLAY CO., LTD., Yongin-Si (KR)

(72) Inventors: YONG-HOON KWON, Yongin-Si (KR); Byunghoon Kim, Yongin-Si (KR); Taeoh Kim, Yongin-Si (KR)

(21) Appl. No.: 18/626,503

(22) Filed: Apr. 4, 2024

(30) Foreign Application Priority Data
Apr. 6, 2023 (KR) 10-2023-0045724

(51) Int. Cl. H10K 59/80; H10K 71/00

(52) U.S. Cl. CPC H10K 59/8721; H10K 59/8722; H10K 71/851

(57) ABSTRACT

A display device includes a substrate. A light emitting element layer is disposed on the substrate and includes a plurality of light emitting diodes. A welding part is disposed on the substrate, covering at least one side surface of the light emitting element layer. and the welding part includes a silicon wafer of the substrate and glass of the window part. A cover window is disposed on the welding part and the light emitting element layer.

This application claims priority under 35 U.S.C. § 119 to Korean Patent Application No. 10-2023-0045724, filed on Apr. 6, 2023, the content of which is herein incorporated by reference in its entirety.

### TECHNICAL FIELD

The disclosure relates to a display device. More specifically, the disclosure relates to a display device including a protective welding and a method of manufacturing the display device.

### DISCUSSION OF THE RELATED ART

A display device is a device that displays an image to provide visual information to a user. The display device may be a flat panel display device such as a liquid crystal display, a field emission display, or a light emitting display. The light emitting display device may include an organic light emitting display device including an organic light emitting diode element as a light emitting element, an inorganic light emitting display device including an inorganic semiconductor element as a light emitting element, or a micro display device including a subminiature light emitting diode (or micro light emitting diode element) as a light emitting element.

Recently, a head mounted display including a light emitting display device has been developed. A Head Mounted Display (HMD) is a glasses-type monitor device of Virtual Reality (VR) or Augmented Reality (AR) that is worn by a user in the form of glasses or a helmet and focuses on a distance close to the eyes.

The display device may include a sealant covering a side surface of the display part to protect the display part between a substrate and a cover window. Forming the sealant may be performed separately.

### SUMMARY

A display device includes a substrate, a light emitting element layer disposed on the substrate and including a plurality of light emitting diodes. A welding part is disposed on the substrate. The welding part covers at least one side surface of the light emitting element layer. A cover window is disposed on the welding part and the light emitting element layer.

The welding part may be disposed between the substrate and the cover window and may be directly connected to each of the substrate and the cover window.

The substrate may include a base substrate defining a plurality of grooves and a plurality of pixel circuit parts respectively accommodated in the plurality of grooves.

The base substrate may include a silicon wafer.

The cover window may include glass.

a side surface of the welding part may be flat.

The side surface of the welding part may be aligned with a side surface of the substrate and a side surface of the cover window.

A side surface of the welding part may be curved, having a concave shape.

The side surface of the welding part may be positioned more inwardly than the side surface of the substrate and a side surface of the cover window.

In an embodiment, the display device may further include a sealant surrounding at least one side surface of the welding part.

The sealant may include a curable resin.

A method of manufacturing a display device includes forming a substrate. A light emitting element layer is formed by forming a plurality of light emitting diodes on the substrate. A cover window is formed on the light emitting element layer. A welding part is formed covering at least one side surface of the light emitting element layer between the substrate and the cover window.

The forming of the substrate may include cutting a mother substrate. The forming of the cover window may include cutting a mother glass substrate.

The forming of the welding part may include forming a preliminary welding part by simultaneously welding the mother substrate and the mother glass substrate.

The simultaneously welding of the mother substrate and the mother glass substrate may be performed using a first laser.

The first laser may be an infrared laser.

The first laser may be a Gaussian laser beam.

The forming of the substrate, the forming of the cover window, and the forming of the welding part may include cutting the mother substrate, the mother glass substrate, and the preliminary welding part along the preliminary welding part.

The forming of the substrate, the forming of the cover window, and the forming of the welding part may be performed using a second laser.

The second laser may be a Bessel laser beam.

The second laser may be cast in a direction from the mother glass substrate to the mother substrate.

The second laser may be cast in a direction from the mother substrate to the mother glass substrate.

The forming of the substrate, the forming of the cover window, and the forming of the welding part may include cutting the mother substrate and the mother glass substrate along an outer edge of the preliminary welding part.

The substrate may include a silicon wafer.

The cover window may include glass.

The welding part may include the silicon wafer of the substrate and the glass of the cover window.

The method may further include forming a sealant surrounding at least one side surface of the welding part.

### BRIEF DESCRIPTION OF THE DRAWINGS

A more complete appreciation of the present disclosure and many of the attendant aspects thereof will be more clearly understood from the following detailed description taken in conjunction with the accompanying drawings.

FIG. 1 is a plan view illustrating a display device according to an embodiment of the present invention.

FIG. 2 is an enlarged view of a pixel of FIG. 1.

FIG. 3 is a cross-sectional view taken along line I-I′ of FIG. 2.

FIG. 4 is a cross-sectional view taken along line II-II′ and line III-III′ of FIG. 1.

FIG. 5 is a cross-sectional view taken along line IV-IV′ and line V-V′ of FIG. 1.

FIG. 6 is a cross-sectional view illustrating an example of FIG. 4.

FIG. 7 is a cross-sectional view illustrating an example of FIG. 4.

FIG. 8 is a plan view illustrating an example of FIG. 2.

FIG. 9 is a plan view illustrating an example of FIG. 2.

FIG. 10 is a cross-sectional view illustrating an example of FIG. 3.

FIGS. 11 to 17 are views illustrating a manufacturing method of a display device according to an embodiment.

FIG. 18 is a view illustrating a method of manufacturing a display device according to an embodiment.

FIGS. 19 and 20 are views illustrating a manufacturing method of a display device according to an embodiment.

FIG. 21 is a view illustrating a manufacturing method of a display device according to an embodiment.

FIG. 22 is a view illustrating an embodiment in which the display device of FIG. 1 is implemented as a virtual reality device.

FIG. 23 is a view illustrating an embodiment in which the display device of FIG. 1 is implemented as a computer monitor.

FIG. 24 is a view illustrating an embodiment in which the display device of FIG. 1 is implemented as a smart phone.

### DETAILED DESCRIPTION

The invention now will be described more fully hereinafter with reference to the accompanying drawings, in which various embodiments are shown. This invention may, however, be embodied in many different forms, and should not necessarily be construed as limited to the embodiments set forth herein. Rather, these embodiments are provided so that this disclosure will be thorough and complete, and will fully convey the scope of the invention to those skilled in the art. Like reference numerals may refer to like elements throughout the specification and the drawings.

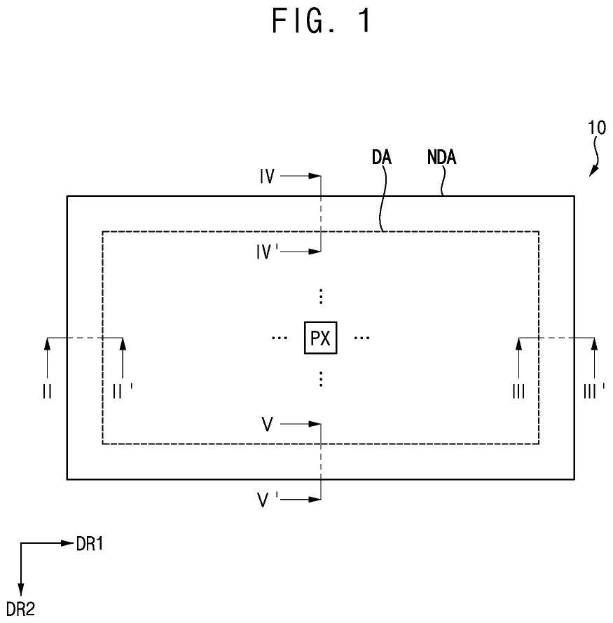

FIG. 1 is a plan view illustrating a display device according to an embodiment of the present invention.

Referring to FIG. 1, a display device 10, according to an embodiment, may include a display area DA and a non-display area NDA.

The display device 10 may have a rectangular planar shape having a pair of long sides extending in a first direction DR1 and a pair of short side extending in a second direction DR2. The second direction DR2 may cross the first direction DR1. However, it is not necessarily limited thereto.

The display area DA may be an area displaying an image. A planar shape of the display area DA may be a rectangular shape or, as shown in FIG. 1, a rectangular shape with rounded corners. However, the planar shape of the display area DA is not necessarily limited thereto, and the display area DA may have various planar shapes such as a circular shape, an elliptical shape, and a polygonal shape other than rectangular.

The non-display area NDA may at least partially surround the display area DA. The non-display area NDA may fully surround the display area DA. The non-display area NDA may be an area that does not display an image. In an embodiment, drivers for displaying an image of the display area DA may be disposed in the non-display area NDA.

Pixels PX may be arranged in a matrix in the display area DA. The pixels PX may be defined as a minimum light emitting unit capable of displaying light. Also, signal lines such as a gate line and a data line may be disposed in the display area DA. The signal lines such as the gate line and the data line may be connected to each of the pixels PX. Each of the pixels PX may receive a gate signal, a data signal, and the like from the signal line.

In an embodiment, the display device 10 may be a subminiature light emitting diode display (or micro light emitting diode display) including a subminiature light emitting diode (or micro light emitting diode) as a light emitting element. However, the present invention is not necessarily limited thereto.

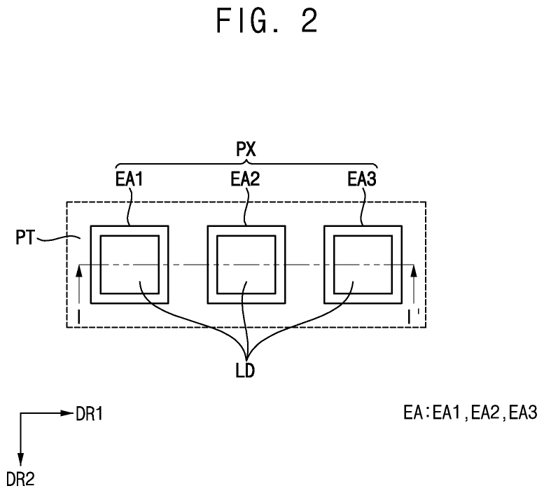

FIG. 2 is an enlarged view of a pixel of FIG. 1.

Referring to FIG. 2, each of the plurality of pixels PX may include a plurality of light emitting areas EA1, EA2, and EA3 emitting light. In FIG. 2, it is illustrated that each of the plurality of pixels PX includes three light emitting areas EA1, EA2, and EA3, but the present invention is not necessarily limited thereto. For example, each of the plurality of pixels PX may include four or more light emitting areas.

Each of the plurality of light emitting areas EA1, EA2, and EA3 may include a light emitting diode LD emitting a first light. The first light may be white light. However, the present invention is not necessarily limited thereto. In addition, although the light emitting diode LD is illustrated having a quadrilateral planar shape, the present invention is not necessarily limited thereto. For example, the light emitting diode LD may have a polygonal shape other than a quadrilateral shape, a circular shape, an elliptical shape, or an atypical shape.

The first light emitting area EA1 may emit a second light. The first light emitting area EA1 may convert the first light emitted from the light emitting diode LD into the second light and emit the second light. For example, the second light may be light in a blue wavelength band. However, the present invention is not necessarily limited thereto.

The second light emitting area EA2 may emit a third light. The second light emitting area EA2 may convert the first light emitted from the light emitting diode LD into the third light and emit the third light. The third light may be light in a green wavelength band. However, the present invention is not necessarily limited thereto.

The third light emitting area EA3 may emit a fourth light. The third light emitting area EA3 may convert the first light emitted from the light emitting diode LD into the fourth light and emit the fourth light. The fourth light may be light in a red wavelength band. However, the present invention is not necessarily limited thereto, and in an embodiment, the light emitting diode LD included in the first light emitting area EA1 may emit a second light of a blue wavelength band, the light emitting diode LD included in the second light emitting region EA2 may emit a third light of a green wavelength band, and the light emitting diode LD included in the third light emitting area EA3 may emit a fourth light of a red wavelength band.

The first light emitting area EA1, the second light emitting area EA2, and the third light emitting area EA3 may be alternately arranged in the first direction DR1. For example, the first light emitting area EA1, the second light emitting area EA2, and the third light emitting area EA3 may be sequentially arranged in the first direction DR1. However, the present invention is not necessarily limited thereto.

The plurality of light emitting areas EA1, EA2, and EA3 may be partitioned by a partition wall PT. The partition wall PT may at least partially surround the light emitting diode LD. The partition wall PT may be spaced apart from the light emitting diode LD. The partition wall PT may have a planar shape such as a mesh shape, a net shape, or a lattice shape.

Each of the plurality of light emitting areas EA1, EA2, and EA3 defined by the partition wall PT may have a rectangular planar shape, but the present invention is not necessarily limited thereto. For example, each of the plurality of light emitting areas EA1, EA2, and EA3 defined by the partition wall PT may have a polygonal shape other than a quadrilateral shape, a circular shape, an elliptical shape, or an atypical shape.

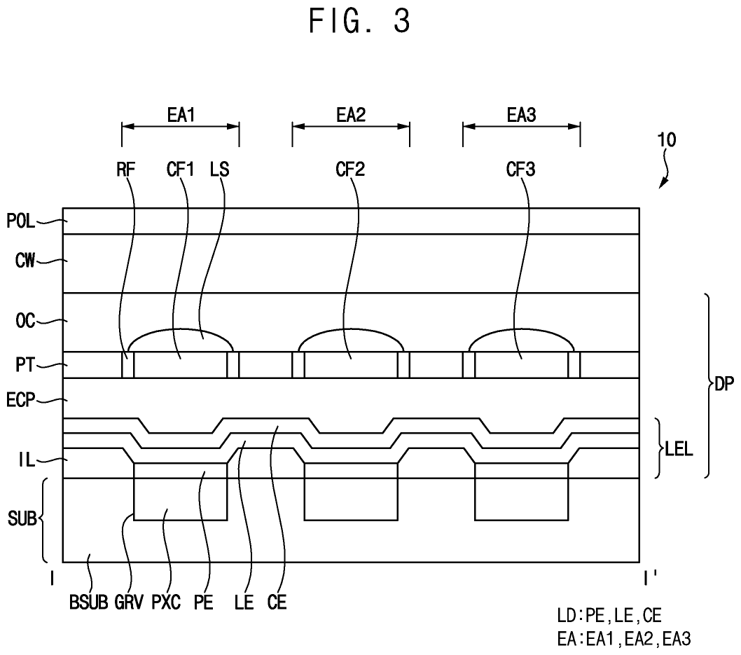

FIG. 3 is a cross-sectional view taken along line I-I′ of FIG. 2.

Referring further to FIG. 3, the display device 10 may include a substrate SUB, a display part DP, a cover window CW, and a polarization layer POL.

In an embodiment, the substrate BSUB may be a semiconductor circuit board. The substrate SUB may include a base substrate BSUB and a plurality of pixel circuit parts PXC. The base substrate BSUB may define a plurality of grooves GRV. Also, the base substrate SUB may include a silicon wafer. The plurality of pixel circuit parts PXC may be accommodated in the plurality of grooves GRV, respectively.

Each of the plurality of pixel circuit parts PXC may include at least one transistor. In addition, each of the plurality of pixel circuit parts PXC may further include at least one capacitor.

The display part DP may be disposed on the substrate SUB. The display part DP may include a light emitting element layer LEL, an encapsulation layer ECP, a color filter layer, a lens part LS, and a planarization layer OC.

The light emitting element layer LEL may be disposed on the substrate SUB. The light emitting element layer LEL may include a plurality of light emitting diodes LD and an insulating layer IL. Each of the plurality of light emitting diodes LD may include a pixel electrode PE, a light emitting layer LE, and a common electrode CE.

The insulating layer IL may be disposed on the substrate SUB. The insulating layer IL may define an opening exposing the plurality of pixel circuit parts PXC.

The plurality of pixel electrodes PE may be respectively disposed on the plurality of pixel circuit parts PXC. The plurality of pixel electrodes PE may be disposed in the opening defined in the insulating layer IL. The plurality of pixel electrodes PE may be connected respectively to the plurality of pixel circuit parts PXC. Accordingly, the pixel electrode PE may receive a pixel voltage or an anode voltage from the pixel circuit part PXC. For example, the pixel electrode PE may include a metal, an alloy, a conductive metal oxide, a transparent conductive material, or the like.

The light emitting layer LE may be disposed on the plurality of pixel electrodes PE and the insulating layer IL. The light emitting layer LE may include an organic light emitting layer including an organic material. The light emitting layer LE may further include a hole injection layer, a hole transport layer, an electron transport layer, and/or an electron injection layer as an auxiliary layer for assisting light emission in some cases.

In an embodiment, the light emitting layer LE may include a plurality of organic light emitting layers. The plurality of organic light emitting layers may be sequentially stacked and provided. For example, the light emitting layer LE may have a tandem structure including the plurality of organic light emitting layers overlapping in a thickness direction and charge generation layers disposed therebetween. Each of overlapping organic light emitting layers may emit light of the same wavelength or may emit light of different wavelengths. For example, the light emitting layer LE including the plurality of organic light emitting layers may emit white light. However, the present invention is not necessarily limited thereto.

The light emitting layer LE may have a shape of a continuous film formed over the plurality of light emitting areas EA1, EA2, and EA3. However, the present invention is not necessarily limited thereto.

The common electrode CE may be disposed on the light emitting layer LE. The common electrode CE may include a conductive material such as a metal, an alloy, a conductive metal nitride, a conductive metal oxide, or a transparent conductive material. The light emitting layer LE may emit light based on a voltage difference between the pixel electrode PE and the common electrode CE.

The common electrode CE may have a shape of a continuous plate formed over the plurality of light emitting areas EA1, EA2, and EA3. For example, the common electrode CE may include a metal, an alloy, a conductive metal oxide, a transparent conductive material, or the like. However, the present invention is not necessarily limited thereto.

The encapsulation layer ECP may be disposed on the light emitting element layer LEL. The encapsulation layer ECP may be disposed on the common electrode CE. The encapsulation layer ECP may include at least one inorganic encapsulation layer and at least one organic encapsulation layer. The encapsulation layer ECP may prevent foreign materials from penetrating into the light emitting element layer LEL.

The color filter layer may be disposed on the encapsulation layer ECP. The color filter layer may include the partition wall PT, a plurality of color filters CF1, CF2, and CF3, and a reflective layer RF.

The partition wall PT may be disposed on the encapsulation layer ECP. The partition wall PT may define the first light emitting area EA1, the second light emitting area EA2, and the third light emitting area EA3 by dividing the first light emitting area EA1, the second light emitting area EA2, and the third light emitting area EA3. The partition wall PT may have a lattice shape throughout the display area DA.

The plurality of color filters CF1, CF2, and CF3 may be disposed in a plurality of openings defined by the partition wall PT. The plurality of color filters CF1, CF2, and CF3 may include a first color filter CF1, a second color filter CF2, and a third color filter CF3.

The first color filter CF1 may overlap the first light emitting area EA1. The first color filter CF1 may transmit the second light among the first light emitted from the light emitting element layer LEL, and may absorb or block the third light and the fourth light. For example, the first color filter CF1 may transmit light in a blue wavelength band and absorb or block light in other wavelength bands, such as green and red.

The second color filter CF2 may overlap the second light emitting area EA2. The second color filter CF2 may transmit the third light and absorb or block the second light and the fourth light. For example, the second color filter CF2 may transmit light in a green wavelength band and absorb or block light in other wavelength bands, such as blue and red.

The third color filter CF3 may overlap the third light emitting area EA3. The third color filter CF3 may transmit the fourth light and absorb or block the second light and the third light. For example, the third color filter CF3 may transmit light in a red wavelength band and absorb or block light in other wavelength bands, such as blue and green.

The reflective layer RF may be disposed in a plurality of openings defined by the partition wall PT. The reflective layer RF may be disposed on side surfaces of the partition wall PT. Among the light emitted from the light emitting element layer LEL, the reflective layer RF may reflect light traveling in a left-side direction and a right-side direction instead of an upper direction. The reflective layer RF may be disposed on the display area DA, and may overlap the first light emitting area EA1, the second light emitting area EA2, and the third light emitting area EA3.

The reflective layer RF may at least partially surround the plurality of color filters CF1, CF2, and CF3 in the display area DA. The reflective layers RF may be spaced apart from each other and may be spaced apart from the reflective layers RF of adjacent color filters. Although a planar shape of the reflective layer RF is shown as a quadrilateral closed loop shape in FIG. 3, it is not necessarily limited thereto and may have various shapes depending on the planar shape of the openings of the partition wall PT.

However, the present invention is not necessarily limited thereto, and in an embodiment, a light blocking layer may be disposed instead of the reflective layer RF. Among the light emitted from the light emitting element layer LEL, the light blocking layer may absorb light traveling in a left-side direction and a right-side direction instead of an upper direction.

The plurality of lens parts LS may be respectively disposed on the plurality of color filters CF1, CF2, and CF3. The plurality of lens parts LS may have a convex lens shape. The plurality of lens parts LS may increase light extraction efficiency.

The planarization layer OC may be disposed on the lens parts LS. The planarization layer OC may flatten an upper surface of the display part DP. The planarization layer OC may include an organic material.

The cover window CW may be disposed on the planarization layer OC. The cover window CW may protect the display part DP and the substrate SUB. The cover window CW may include glass. The glass may be tempered glass.

The polarization layer POL may be disposed on the cover window CW. The polarization layer POL may reduce reflection of external light of the display device 10. Accordingly, visibility of the display device 10 may be increased by reducing reflection of external light.

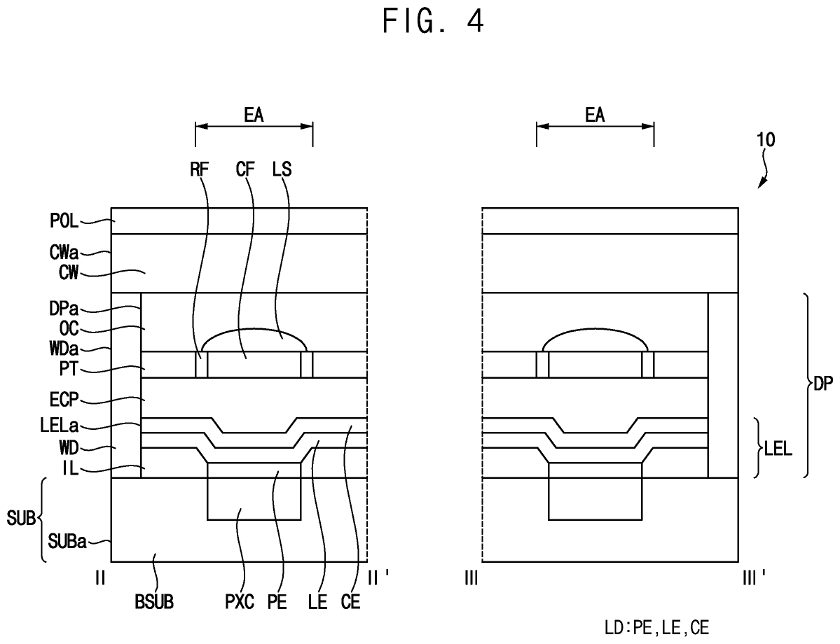

FIG. 4 is a cross-sectional view taken along line II-II′ and line III-III′ of FIG. 1. FIG. 5 is a cross-sectional view taken along line IV-IV′ and line V-V′ of FIG. 1.

Further referring to FIGS. 4 and 5, the display device 10 may further include a welding part WD.

In an embodiment, the welding part WD may be disposed between the substrate SUB and the cover window CW. The welding part WD may be connected to the substrate SUB and the cover window CW. The welding part WD may be formed by welding the substrate SUB and the cover window CW. Therefore, the welding part WD may include a silicon wafer and glass. For example, the welding part WD may include the silicon wafer of the substrate SUB and the glass of the cover window CW.

In an embodiment, a side surface WDa of the welding part WD may be flat. For example, the side surface WDa of the welding part WD may have a flat shape and might not have a curved shape. Also, the side surface WDa of the welding part WD may be substantially aligned with a side surface SUBa of the substrate SUB and a side surface CWa of the cover window CW. For example, the side surface WDa of the welding part WD may be positioned on the same line as the side surface SUBa of the substrate SUB and the side surface CWa of the cover window CW.

The welding part WD may cover at least one of the side surfaces DPa of the display part DP, and may cover at least one side surface LELa of the light emitting element layer LEL. For example, the welding part WD may cover at least three of side surfaces DPa of the display part DP. The other side surface DPb of the display part DP may be connected to a printed circuit board, so unlike the three side surfaces DPa, the welding part WD might not be disposed. A sealing part SP may cover the other side surface DPb of the display part DP. The sealing part SP may include a curable resin.

However, the present invention is not necessarily limited thereto, and in an embodiment, the welding part WD may be disposed on all side surfaces of the display part DP. In an embodiment, the welding part WD may be disposed on two or one side surface(s) of the display part DP.

In an embodiment, since the display device 10 includes the welding part WD including a silicon wafer and glass and covering at least one side surface DPa of the display part DP, so that the side surfaces DPa of the display part DP may be effectively covered and protected. Accordingly, reliability of the display device 10 may be increased.

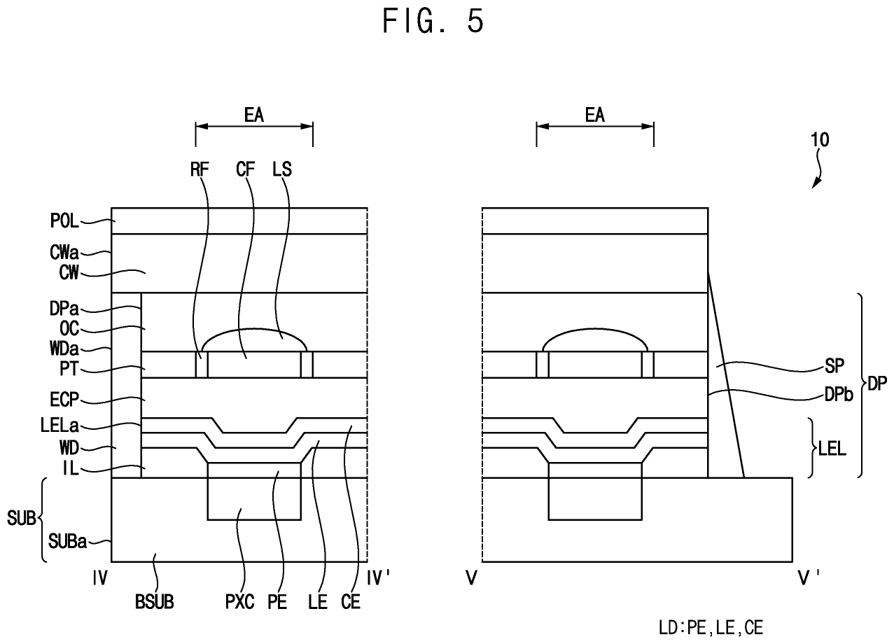

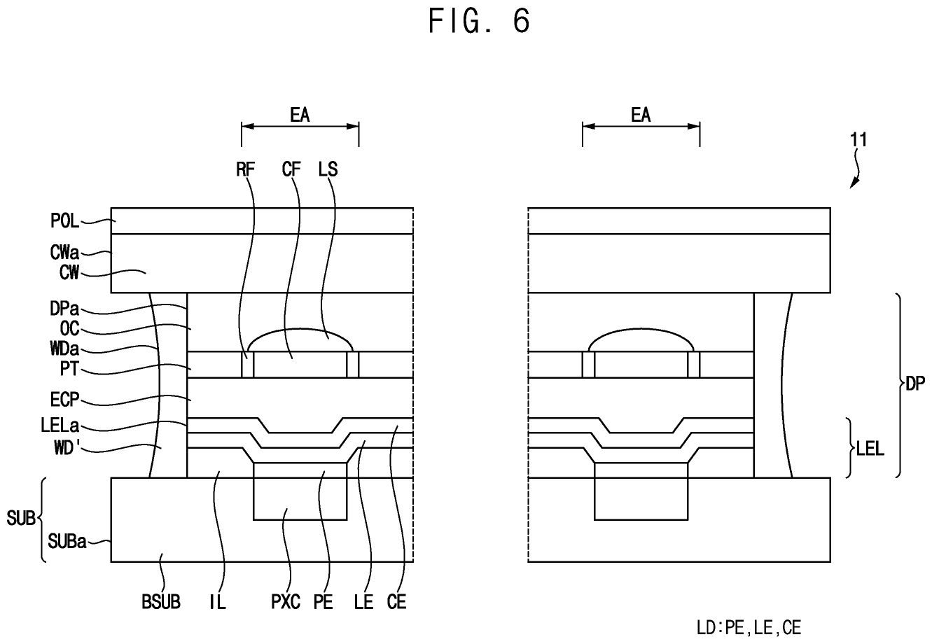

FIG. 6 is a cross-sectional view illustrating another example of FIG. 4.

A display device 11 described with reference to FIG. 6 may be substantially the same as the display device 10 described with reference to FIGS. 4 and 5 except for a welding part. Therefore, to the extent that a detailed description of an element has been omitted, it may be understood that the element is at least similar to a corresponding element that has been described in detail elsewhere within the instant specification.

Referring to FIG. 6, the display device 11 may include the substrate SUB, the display part DP, the cover window CW, the polarization layer POL, and a welding part WD′.

The welding part WD′ may be disposed between the substrate SUB and the cover window CW, and may cover at least one side surface LELa of the light emitting element layer LEL.

In an embodiment, a side surface WDa of the welding part WD′ may be curved having a concave shape. For example, the side surface WDa of the welding part WD′ may have an inwardly concave curved surface. In addition, the side surface WDa of the welding part WD′ may be positioned inner than the side surface SUBa of the substrate SUB and the side surface CWa of the cover window CW. However, the present invention is not necessarily limited thereto.

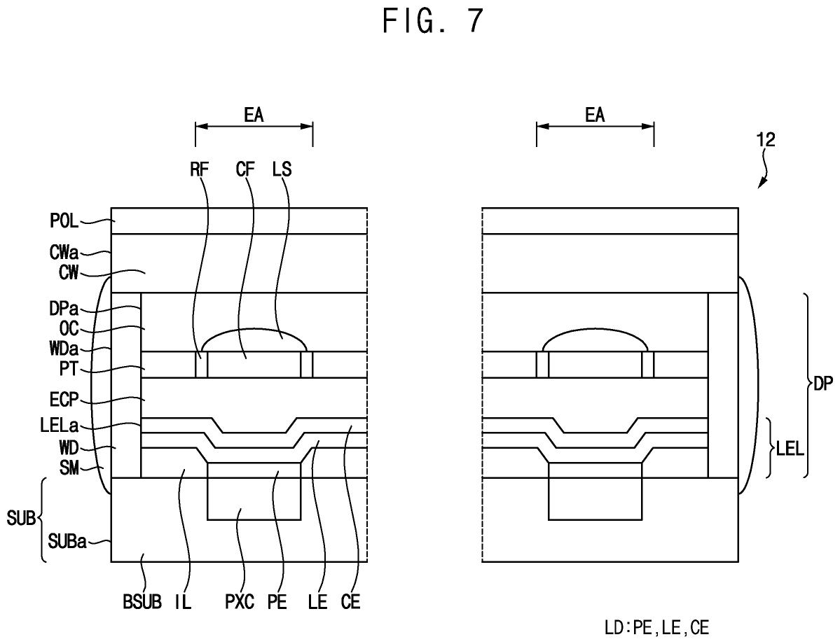

FIG. 7 is a cross-sectional view illustrating an example of the arrangement of FIG. 4.

A display device 12 described with reference to FIG. 7 may be substantially the same as the display device 10 described with reference to FIGS. 4 and 5 except for a sealant SM. Therefore, to the extent that a detailed description of an element has been omitted, it may be understood that the element is at least similar to a corresponding element that has been described in detail elsewhere within the instant specification.

Referring to FIG. 7, the display device 12 may include the substrate SUB, the display part DP, the cover window CW, the polarization layer POL, the welding part WD, and the sealant SM.

In an embodiment, the sealant SM may at least partially surround at least one side surface WDa of the welding part WD. The sealant SM may include a curable resin. Accordingly, the side surface of the sealant SM may be a curved surface having a convex shape.

In an embodiment, since the display device 12 further includes the sealant SM, the side surfaces DPa of the display part DP may be effectively covered and protected. Accordingly, reliability of the display device 12 may be increased.

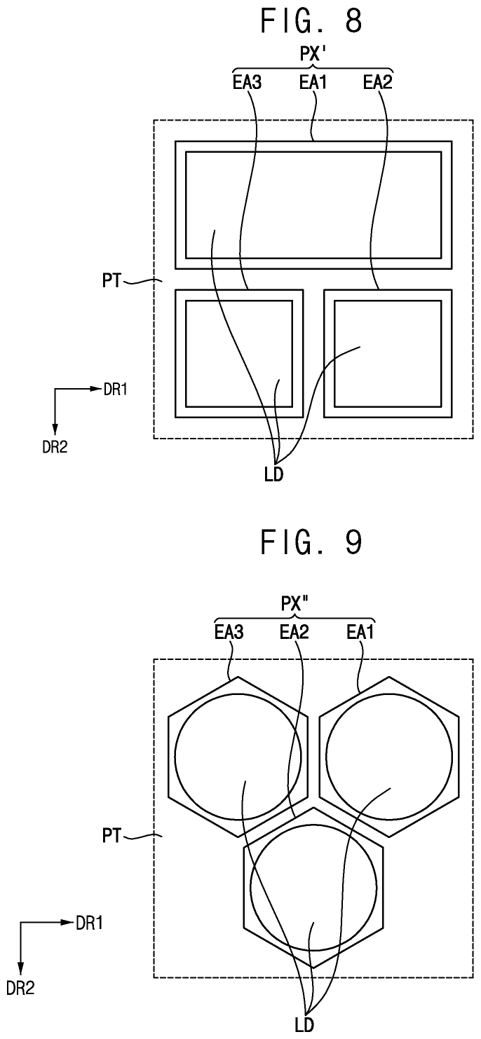

FIG. 8 is a plan view illustrating an example of the arrangement of FIG. 2.

A pixel PX′ described with reference to FIG. 8 is the same as the pixel PX described with reference to FIGS. 2 to 7 except for an arrangement relationship between the first to third light emitting areas EA1, EA2, and EA3. Therefore, to the extent that a detailed description of an element has been omitted, it may be understood that the element is at least similar to a corresponding element that has been described in detail elsewhere within the instant specification.

Referring to FIG. 8, the pixel PX′ may include the plurality of light emitting areas EA1, EA2, and EA3 emitting light. Each of the plurality of light emitting areas EA1, EA2, and EA3 may include a light emitting diode LD emitting a first light. The first light emitting area EA1 may convert the first light emitted from the light emitting diode LD into the second light and emit the second light. The second light emitting area EA2 may convert the first light emitted from the light emitting diode LD into the third light and emit the third light. The third light emitting area EA3 may convert the first light emitted from the light emitting diode LD into the fourth light and emit the fourth light.

However, the present invention is not necessarily limited thereto, and in an embodiment, the light emitting diode LD included in the first light emitting area EA1 may emit the second light, the light emitting diode LD included in the second light emitting area EA2 may emit the third light, and the light emitting diode LD included in the third light emitting area EA3 may emit the fourth light.

In an embodiment, the first light emitting area EA1 may have a larger area (or size) than the second light emitting area EA2 and the third light emitting area EA3. The second light emitting area EA2 and the third light emitting area EA3 may be spaced apart from the first light emitting area EA1 in the second direction DR2. Also, the third light emitting area EA3 may be spaced apart from the second light emitting area EA2 in the first direction DR1. However, the present invention is not necessarily limited thereto.

The plurality of light emitting areas EA1, EA2, and EA3 may be partitioned by the partition wall PT. The partition wall PT may at least partially surround the light emitting diode LD. The partition wall PT may be spaced apart from the light emitting diode LD. Each of the plurality of light emitting areas EA1, EA2, and EA3 defined by the partition wall PT may have a rectangular planar shape, but the present invention is not necessarily limited thereto.

FIG. 9 is a plan view illustrating an example of the arrangement of FIG. 2.

A pixel PX″ described with reference to FIG. 9 may be the same as the pixel PX described with reference to FIGS. 2 to 7 except for an arrangement relationship between the first to third light emitting areas EA1, EA2, and EA3. Therefore, to the extent that a detailed description of an element has been omitted, it may be understood that the element is at least similar to a corresponding element that has been described in detail elsewhere within the instant specification.

Referring to FIG. 9, the pixel PX″ may include the plurality of light emitting areas EA1, EA2, and EA3 emitting light. Each of the plurality of light emitting areas EA1, EA2, and EA3 may include a light emitting diode LD emitting a first light. The first light emitting area EA1 may convert the first light emitted from the light emitting diode LD into the second light and emit the second light. The second light emitting area EA2 may convert the first light emitted from the light emitting diode LD into the third light and emit the third light. The third light emitting area EA3 may convert the first light emitted from the light emitting diode LD into the fourth light and emit the fourth light.

However, the present invention is not necessarily limited thereto, and in an embodiment, the light emitting diode LD included in the first light emitting area EA1 may emit the second light, the light emitting diode LD included in the second light emitting area EA2 may emit the third light, and the light emitting diode LD included in the third light emitting area EA3 may emit the fourth light.

In one embodiment, the first light emitting area EA1 may be spaced apart from the third light emitting area EA3 in the first direction DR1. The second light emitting area EA2 may be spaced apart from the first light emitting area EA1 and the third light emitting area EA3 in the second direction DR2. Centers of the first to third light emitting areas EA1, EA2, and EA3 may form a triangular structure with each other. However, the present invention is not necessarily limited thereto.

The plurality of light emitting areas EA1, EA2, and EA3 may be partitioned by the partition wall PT. The partition wall PT may at least partially surround the light emitting diode LD. The partition wall PT may be spaced apart from the light emitting diode LD. Each of the plurality of light emitting areas EA1, EA2, and EA3 defined by the partition wall PT may have a hexagonal planar shape, and the light emitting diode LD may have a circular planar shape, but the present invention is not necessarily limited thereto.

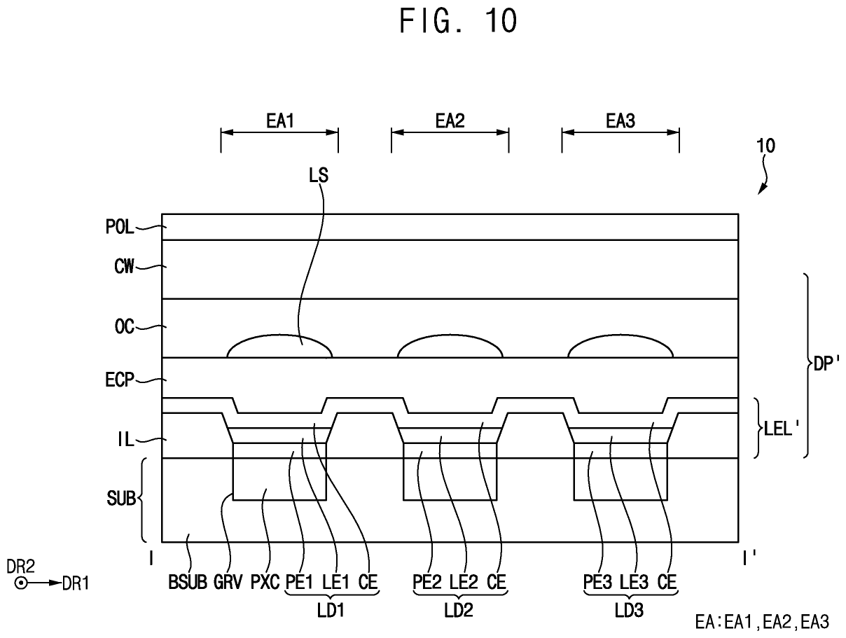

FIG. 10 is a cross-sectional view illustrating an example of the arrangement of FIG. 3.

A display device 13 described with reference to FIG. 10 may be substantially the same as the display device 10 described with reference to FIG. 3 except for a structure of a display part DP′. Accordingly, to the extent that a detailed description of an element has been omitted, it may be understood that the element is at least similar to a corresponding element that has been described in detail elsewhere within the instant specification.

Referring to FIG. 10, the display device 13 may include the substrate SUB, the display part DP′, the cover window CW, and the polarization layer POL.

The display part DP′ may be disposed on the substrate SUB. The display part DP′ may include a light emitting element layer LEL′, the encapsulation layer ECP, the lens part LS, and the planarization layer OC. For example, the display part DP′ might not include the color filter layer.

The light emitting element layer LEL′ may be disposed on the substrate SUB. The light emitting element layer LEL′ may include first to third light emitting diodes LD1, LD2, and LD3 and an insulating layer IL. The first light emitting diode LD1 may include a first pixel electrode PE1, a first light emitting layer LE1, and a common electrode CE. The second light emitting diode LD2 may include a second pixel electrode PE2, a second light emitting layer LE2, and a common electrode CE. The third light emitting diode LD3 may include a third pixel electrode PE3, a third light emitting layer LE3, and a common electrode CE.

The first to third pixel electrodes PE1, PE2, and PE3 may be respectively disposed on the plurality of pixel circuit parts PXC. The first to third pixel electrodes PE1, PE2, and PE3 may be disposed in an opening defined in the insulating layer IL. The first to third pixel electrodes PE1, PE2, and PE3 may be connected to the plurality of pixel circuit parts PXC, respectively. Accordingly, the first to third pixel electrodes PE1, PE2, and PE3 may receive a pixel voltage or an anode voltage from the pixel circuit part PXC. For example, the first to third pixel electrodes PE1, PE2, and PE3 may include a metal, an alloy, a conductive metal oxide, a transparent conductive material, or the like.

The first pixel electrode PE1 may overlap the first light emitting area EA1. The second pixel electrode PE2 may overlap the second light emitting area EA2. The third pixel electrode PE3 may overlap the third light emitting area EA3.

The first to third light emitting layers LE1, LE2, and LE3 may be respectively disposed on the plurality of pixel circuit parts PXC. The first to third light emitting layers LE1, LE2, and LE3 may be disposed in the opening defined in the insulating layer IL.

For example, the first light emitting layer LE1 may be disposed on the first pixel electrode PE1. The second light emitting layer LE2 may be disposed on the second pixel electrode PE2. The third light emitting layer LE3 may be disposed on the third pixel electrode PE3. For example, the first light emitting layer LE1 may overlap the first light emitting area EA1. The second light emitting layer LE2 may overlap the second light emitting area EA2. The third light emitting layer LE3 may overlap the third light emitting area EA3.

Each of the first to third light emitting layers LE1, LE2, and LE3 may include an organic light emitting layer including an organic material. In addition, each of the first to third light emitting layers LE1, LE2, and LE3 may further include a hole injection layer, a hole transport layer, an electron transport layer, and/or an electron injection layer.

The common electrode CE may have a shape of a continuous plate formed over the plurality of light emitting areas EA1, EA2, and EA3. However, the present invention is not necessarily limited thereto. The common electrode CE may include a metal, an alloy, a conductive metal oxide, a transparent conductive material, or the like. However, the present invention is not necessarily limited thereto.

As a result, the first light emitting diode LD1 may overlap the first light emitting area EA1, the second light emitting diode LD2 may overlap the second light emitting area EA2, and the third light emitting diode LD3 may overlap the third light emitting area EA3.

In an embodiment, the first light emitting diode LD1 may emit the second light. Accordingly, the first light emitting area EA1 may emit the second light emitted from the first light emitting diode LD1. For example, the second light may be light in a blue wavelength band. However, the present invention is not necessarily limited thereto.

In an embodiment, the second light emitting diode LD2 may emit the third light. Accordingly, the second light emitting area EA2 may emit the third light emitted from the second light emitting diode LD2. For example, the third light may be light in a green wavelength band. However, the present invention is not necessarily limited thereto.

In an embodiment, the third light emitting diode LD3 may emit the fourth light. Accordingly, the third light emitting area EA3 may emit the fourth light emitted from the third light emitting diode LD3. For example, the fourth light may be light in a red wavelength band. However, the present invention is not necessarily limited thereto.

Since the light emitting diodes disposed in the first to third light emitting areas EA1, EA2, and EA3 emit light of different colors, the display device 13 might not include the color filter layer. For example, the lens parts LS and the planarization layer OC may be directly disposed on the encapsulation layer ECP. As the color filter layer is omitted, a stacked structure of the display part DP′ may be simplified. Accordingly, the stacked structure of the display device 13 may be simplified, and the efficiency of the manufacturing process of the display device 13 may be increased.

The display device 13 may include a welding part covering at least one side surface of the display part DP′. For example, even when the display part DP′ has the stacked structure of FIG. 10, substantially similar to FIG. 4, at least one side surface of the display part DP′ may be covered by the welding part.

FIGS. 11 to 17 are views illustrating a manufacturing method of a display device according to an embodiment.

A method of manufacturing the display device described with reference to FIGS. 11 to 17 may be a method of manufacturing the display device 10 of FIG. 4. Therefore, to the extent that a detailed description of an element has been omitted, it may be understood that the element is at least similar to a corresponding element that has been described in detail elsewhere within the instant specification.

Referring to FIG. 11, a mother substrate MSUB may be formed. The mother substrate MSUB may be formed of a silicon wafer. The mother substrate MSUB may include a plurality of substrates (e.g., the substrate SUB of FIG. 3). For example, the plurality of substrates may be formed by cutting the mother substrate MSUB. Also, a plurality of pixel circuit parts (e.g., the pixel circuit parts PXC of FIG. 3) may be formed on the mother substrate MSUB.

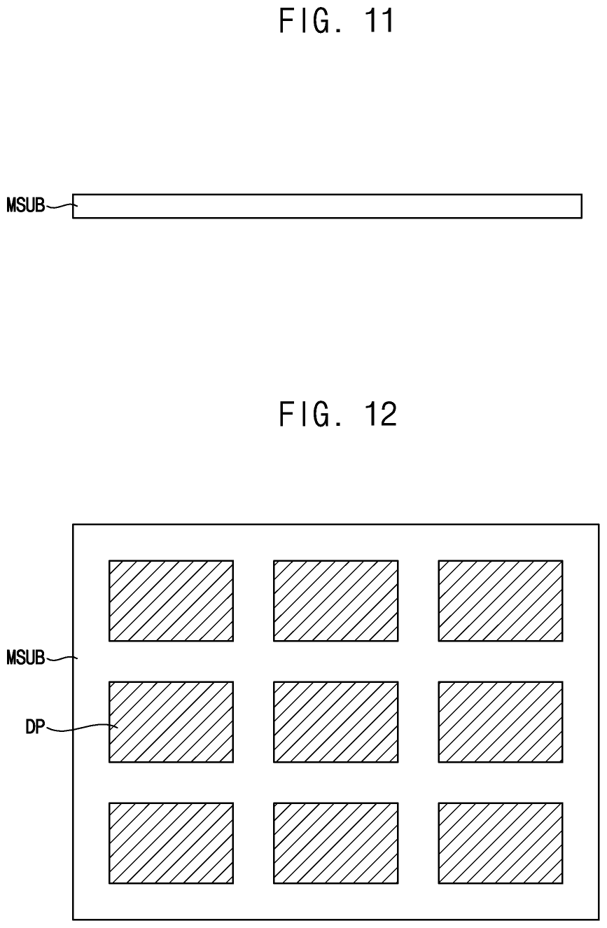

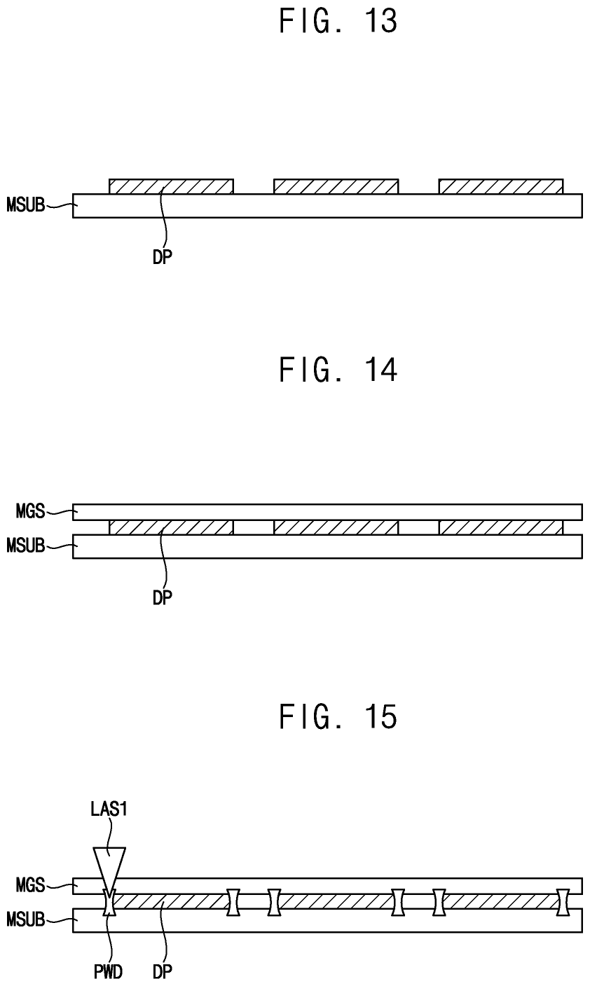

FIG. 12 is a plan view illustrating a method of manufacturing a display device according to an embodiment. FIG. 13 is a cross-sectional view of FIG. 12.

Further referring to FIGS. 12 and 13, a plurality of display parts DP may be formed on the mother substrate MSUB. Each of the plurality of display parts DP may include a light emitting element layer (e.g., the light emitting element layer LEL of FIG. 3). For example, a plurality of light emitting diodes (e.g., light emitting diodes LD of FIG. 2) may be formed on the mother substrate MSUB. In addition, an encapsulation layer may be formed on the light emitting element layer, and a partition wall and a plurality of color filters may be formed on the encapsulation layer. A plurality of lenses may be respectively formed on the plurality of color filters, and a planarization layer may be formed on the plurality of lenses (referring to FIG. 3).

In the views, it is illustrated that nine display parts DP are included in one mother substrate MSUB, but the present invention is not necessarily limited thereto.

Referring further to FIG. 14, a mother glass substrate MGS may be formed on the display part DP. The mother glass substrate MGS may be formed of glass. The glass may be tempered glass. The mother glass substrate MGS may include a plurality of cover windows (e.g., the cover window CW of FIG. 3). For example, the plurality of cover windows may be formed by cutting the mother glass substrate MGS.

Referring to FIGS. 15 to 17, the welding part WD may be formed between the substrate SUB and the cover window CW. The welding part WD may cover at least one side surface of the display part DP including the light emitting element layer LEL.

Referring to FIG. 15, a preliminary welding part PWD may be formed between the mother substrate MSUB and the mother glass substrate MGS.

In an embodiment, the preliminary welding part PWD may be formed by simultaneously welding the mother substrate MSUB and the mother glass substrate MGS. The mother substrate MSUB and the mother glass substrate MGS may be simultaneously welded by a first laser LAS1. In this case, the first laser LAS1 may be cast in a direction from the mother glass substrate MGS to the mother substrate MSUB. However, the present invention is not necessarily limited thereto.

In an embodiment, the first laser LAS1 may be an infrared laser. For example, the first laser LAS1 may be an infrared pulse laser. In this case, the pulse width may be about 10 ps or less. Also, the first laser LAS1 may be a Gaussian laser beam. Therefore, when the first laser LAS1 is cast toward the mother substrate MSUB and the mother glass substrate MGS, the mother substrate MSUB and the mother glass substrate MGS are partially melted and the preliminary welding part PWD may be formed. Accordingly, the preliminary welding part PWD may include a silicon wafer and glass.

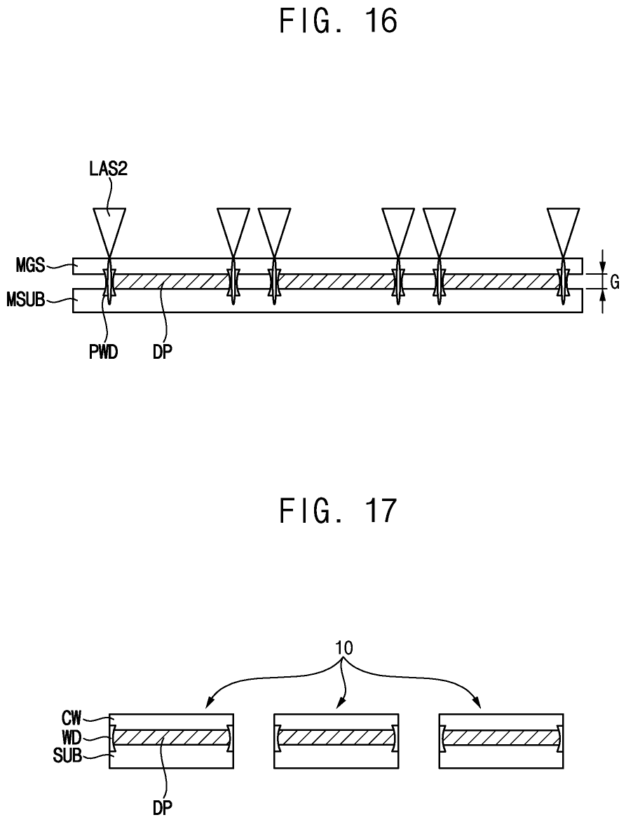

Referring to FIGS. 16 and 17, the mother substrate MSUB, the mother glass substrate MGS, and the preliminary welding part PWD may be cut along the preliminary welding part PWD to form the plurality of substrates SUB, the plurality of cover windows CW, and the plurality of welding parts WD. The mother substrate MSUB, the mother glass substrate MGS, and the preliminary welding part PWD may be simultaneously cut by a second laser LAS2. In this case, the second laser LAS2 may be cast in a direction from the mother glass substrate MGS to the mother substrate MSUB. However, the present invention is not necessarily limited thereto.

In an embodiment, the second laser LAS2 may be an infrared laser. For example, the second laser LAS2 may be an infrared pulse laser. Also, the second laser LAS2 may be a Bessel laser beam. Therefore, when the second laser LAS2 is cast toward the mother substrate MSUB, the mother glass substrate MGS, and the preliminary welding part PWD, the mother substrate MSUB, the mother glass substrate MGS, and the preliminary welding part PWD may be cut.

A distance G between the mother glass substrate MGS and the mother substrate MSUB may be about 10 micrometers or less. When the distance G between the mother glass substrate MGS and the mother substrate MSUB is greater than about 10 micrometers, since the distance G between the mother glass substrate MGS and the mother substrate MSUB is far, it might not be easy to form the preliminary welding part PWD by simultaneously welding the mother glass substrate MGS and the mother substrate MSUB through the first laser LAS1.

In an embodiment, the preliminary welding part PWD may be formed between the mother substrate MSUB and the mother glass substrate MGS, a transmittance of the second laser LAS2 with respect to the mother substrate MSUB and the mother glass substrate MGS is increased so that the mother substrate MSUB, the mother glass substrate MGS, and the preliminary welding part PWD may be cut simultaneously.

Therefore, the plurality of substrates SUB formed from the mother substrate MSUB, the plurality of display parts DP respectively disposed on the plurality of substrates SUB, and the plurality of cover windows CW formed from the mother glass substrate MGS and on the plurality of display parts DP may be formed. Also, the welding part WD covering at least one side surface of the display part DP may be formed between the substrate SUB and the cover window CW. Accordingly, a plurality of display devices 10 including the substrate SUB, the display part DP, the cover window CW, and the welding part WD may be formed.

In addition, a plurality of polarization layers (e.g., the polarization layer POL of FIG. 3) may be additionally formed on the plurality of cover windows CW, respectively.

In an embodiment, since the preliminary welding part PWD may be formed by simultaneously welding the mother substrate MSUB and the mother glass substrate MGS, an additional process for forming a sealant covering a side surface of the display part DP might not be required in the manufacturing process of the display device 10. Also, by forming the preliminary welding part PWD, the mother substrate MSUB and the mother glass substrate MGS may be simultaneously cut. Accordingly, the manufacturing process of the display device 10 may be simplified, and efficiency in the manufacturing process may be increased.

FIG. 18 is a view illustrating a method of manufacturing a display device according to an embodiment.

The manufacturing method of the display device described with reference to FIG. 18 may be the same as the manufacturing method of the display device described with reference to FIGS. 11 to 17 except for a direction in which the second laser LAS2 is cast.

Referring to FIGS. 17 and 18, the mother substrate MSUB, the mother glass substrate MGS, and the preliminary welding part PWD may be cut along the preliminary welding part PWD to form the plurality of substrates SUB, the plurality of cover windows CW, and the plurality of welding parts WD. The mother substrate MSUB, the mother glass substrate MGS, and the preliminary welding part PWD may be simultaneously cut by the second laser LAS2. In this case, the second laser LAS2 may be cast in a direction from the mother substrate MSUB to the mother glass substrate MGS. However, the present invention is not necessarily limited thereto.

In an embodiment, the second laser LAS2 may be an infrared laser. For example, the second laser LAS2 may be an infrared pulse laser. Also, the second laser LAS2 may be a Bessel laser beam. Therefore, when the second laser LAS2 is cast toward the mother substrate MSUB, the mother glass substrate MGS, and the preliminary welding part PWD, the mother substrate MSUB, the mother glass substrate MGS, and the preliminary welding part PWD may be cut.

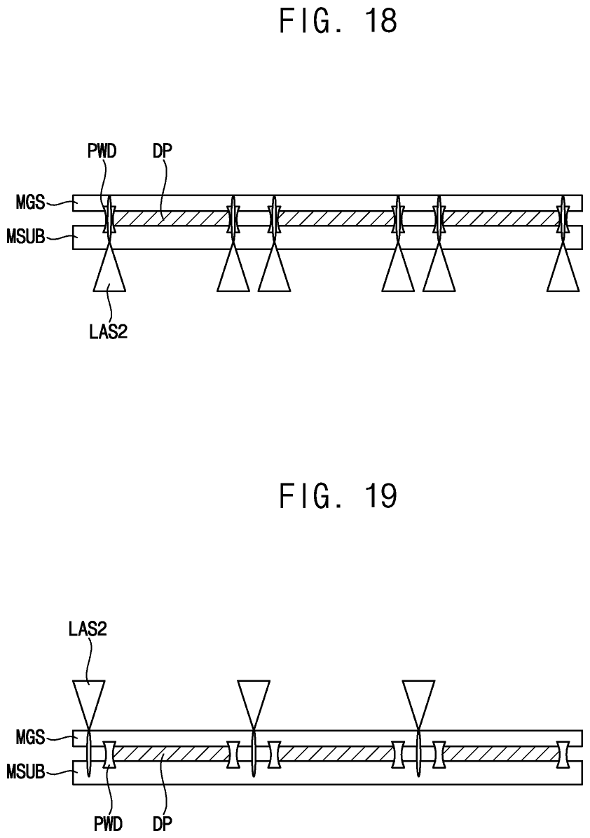

FIGS. 19 and 20 are views illustrating a manufacturing method of a display device according to an embodiment.

A method of manufacturing the display device described with reference to FIGS. 19 and 20 may be the same as the method of manufacturing the display device described with reference to FIGS. 11 to 17 except for a step of casting the second laser LAS2. Also, the method of manufacturing the display device described with reference to FIGS. 19 and 20 may be a method of manufacturing the display device 11 described with reference to FIG. 6.

Referring to FIGS. 19 and 20, the mother substrate MSUB and the mother glass substrate MGS may be cut along the outer edge of the preliminary welding part PWD to form a plurality of substrates SUB and a plurality of cover windows CW. For example, at this time, since a gap between adjacent preliminary welding parts PWD among the preliminary welding parts PWD may be cut, the welding part WD′ may be formed without cutting the preliminary welding part PWD.

The mother substrate MSUB and the mother glass substrate MGS may be simultaneously cut by the second laser LAS2. However, the present invention is not necessarily limited thereto, and in an embodiment, the mother substrate MSUB and the mother glass substrate MGS might not be cut simultaneously but may be cut separately. Also, in an embodiment, the mother substrate MSUB and the mother glass substrate MGS may be cut by a cutting tool other than a laser.

In an embodiment, since the mother substrate MSUB and the mother glass substrate MGS may be cut along the outer edge of the preliminary welding part PWD, the side surface of the welding part WD′ may be positioned inner than the side surface of the substrate SUB and the side surface of the cover window CW. Also, the side surface of the welding part WD′ may be a curved surface having a concave shape. However, the present invention is not necessarily limited thereto.

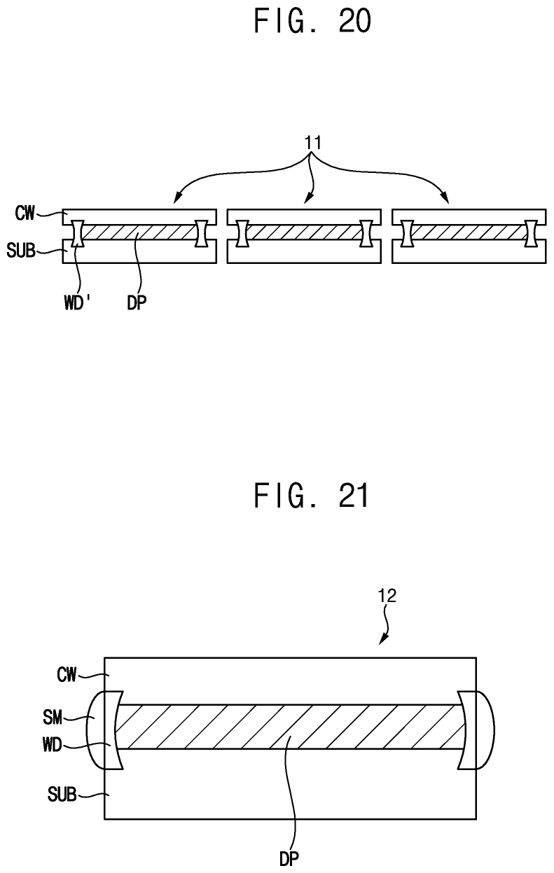

FIG. 21 is a view illustrating a manufacturing method of a display device according to an embodiment.

The manufacturing method of the display device described with reference to FIG. 21 may be the same as the manufacturing method of the display device described with reference to FIGS. 11 to 17 except for a step of forming the sealant SM. Also, the method of manufacturing the display device described with reference to FIG. 21 may be the method of manufacturing the display device 12 described with reference to FIG. 7.

Referring to FIG. 21, the sealant SM may be formed in the display device 12 to surround at least one side surface of the welding part WD. The sealant SM may be formed of a curable resin.

In an embodiment, the reliability of the display device 12 may be increased by further forming the sealant SM at least partially surrounding at least one side surface of the welding part WD.

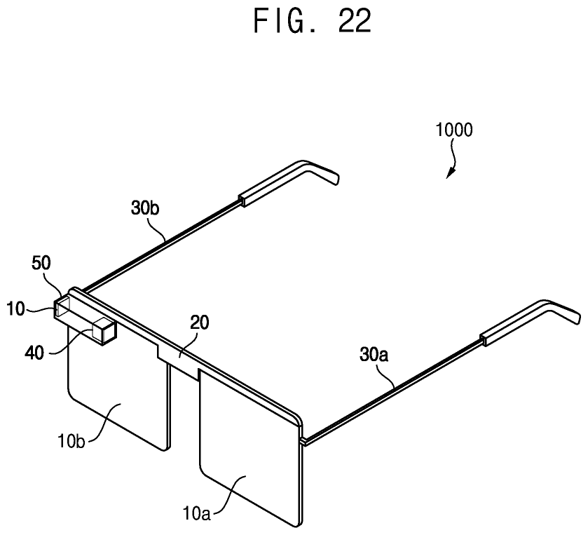

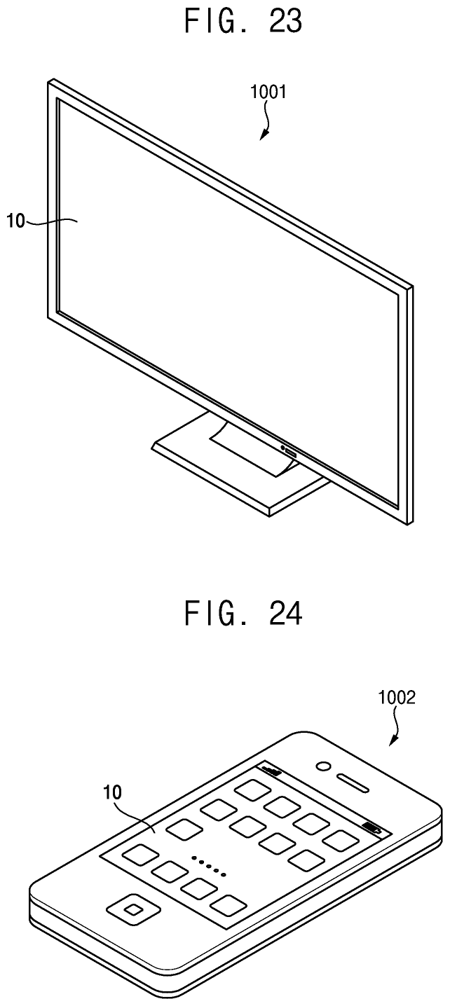

FIG. 22 is a view illustrating an embodiment in which the display device of FIG. 1 is implemented as a virtual reality device. FIG. 23 is a view illustrating an embodiment in which the display device of FIG. 1 is implemented as a computer monitor. FIG. 24 is a view illustrating an embodiment in which the display device of FIG. 1 is implemented as a smart phone.

Referring to FIG. 22, the display device 10 may be implemented as a virtual reality device 1000. For example, the display device 10, according to an embodiment of the present invention, may be applied to the virtual reality device 1000.

The virtual reality device 1000 may be a glasses type device. The virtual reality device 1000 may include the display device 10, a left eye lens 10a, a right eye lens 10b, a support frame 20, eyeglass frame legs 30a and 30b, a reflective member 40, and a display device accommodating part 50.

Although FIG. 22 illustrates the virtual reality device 1000 including the eyeglass frame legs 30a and 30b, in an embodiment, the virtual reality device 1000 may also be applied to a head mounted display including a head mounted band that can be attached to the head instead of the eyeglass frame legs 30a and 30b. For example, the virtual reality device 1000 is not necessarily limited to that shown in FIG. 22 and may be applied in various forms to various other electronic devices.

The display device accommodating part 50 may include the display device 10 and the reflective member 40. An image displayed on the display device 10 may be reflected by the reflective member 40 and provided to the right eye of the user through the right eye lens 10b. Due to this, the user can view the virtual reality image displayed on the display device 10 through the right eye.

Although FIG. 22 illustrates that the display device accommodating part 50 is disposed at the right end of the support frame 20, the present invention is not necessarily limited thereto. For example, the display device accommodating part 50 may be disposed at the left end of the support frame 20. In this case, the image displayed on the display device 10 may be reflected by the reflective member 40 and provided to the user's left eye through the left eye lens 10a. As a result, the user can view the virtual reality image displayed on the display device 10 through the left eye. Alternatively, the display device accommodating part 50 may be disposed at both the left end and the right end of the support frame 20. In this case, the user can view the virtual reality image displayed on the display device 10 through both the left and right eyes.

Referring to FIG. 23, the display device 10 may be implemented as a computer monitor 1001. As described above, as the welding part WD covers the display part DP included in the display device 10, the reliability of the computer monitor 1001 including the display device 10 may be increased.

Referring to FIG. 24, the display device 10 may be implemented as a smart phone 1002. As described above, as the welding part WD may cover the display part DP included in the display device 10, the reliability of the smartphone 1002 including the display device 10 can be increased.

However, display devices according to embodiments of the present invention are not necessarily limited thereto. For example, display devices according to embodiments of the present invention may be implemented as a vehicle display device, a mobile phone, a video phone, a smart pad, a smart watch, a tablet PC, a vehicle navigation device, a television, a laptop computer, head mounted display (HMD), or the like.

The invention should not necessarily be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention.

What is claimed is:

1. A display device, comprising:
a substrate;
a light emitting element layer disposed on the substrate and including a plurality of light emitting diodes;
a welding part disposed on the substrate, the welding part covering at least one side surface of the light emitting element layer, and
a cover window disposed on the welding part and the light emitting element layer.

2. The display device of claim 1, wherein the welding part is disposed between the substrate and the cover window and is directly connected to each of the substrate and the cover window.

3. The display device of claim 2, wherein the substrate includes:
a base substrate defining a plurality of grooves; and
a plurality of pixel circuit parts respectively accommodated in the plurality of grooves.

4. The display device of claim 3, wherein the base substrate includes a silicon wafer.

5. The display device of claim 1, wherein the cover window includes glass.

6. The display device of claim 1, wherein a side surface of the welding part is flat.

7. The display device of claim 6, wherein the side surface of the welding part is aligned with a side surface of the substrate and a side surface of the cover window.

8. The display device of claim 1, wherein a side surface of the welding part is curved, and having a concave shape.

9. The display device of claim 8, wherein the side surface of the welding part is positioned more inwardly than a side surface of the substrate and a side surface of the cover window.

10. The display device of claim 1, further comprising:
a sealant surrounding at least one side surface of the welding part.

11. The display device of claim 10, wherein the sealant includes a curable resin.

12. A method of manufacturing a display device, the method comprising:
forming a substrate;
forming a light emitting element layer by forming a plurality of light emitting diodes on the substrate;
forming a cover window on the light emitting element layer; and
forming a welding part covering at least one side surface of the light emitting element layer between the substrate and the cover window.

13. The method of claim 12, wherein the forming of the substrate includes cutting a mother substrate, and
wherein the forming of the cover window includes cutting a mother glass substrate.

14. The method of claim 13, wherein the forming of the welding part includes forming a preliminary welding part by simultaneously welding the mother substrate and the mother glass substrate.

15. The method of claim 14, wherein the simultaneous welding of the mother substrate and the mother glass substrate is performed using a first laser.

16. The method of claim 15, wherein the first laser is an infrared laser.

17. The method of claim 15, wherein the first laser is a Gaussian laser beam.

18. The method of claim 14, wherein the forming of the substrate, the forming of the cover window, and the forming of the welding part include:
cutting the mother substrate, the mother glass substrate, and the preliminary welding part along the preliminary welding part.

19. The method of claim 18, wherein the forming of the substrate, the forming of the cover window, and the forming of the welding part are performed using a second laser.

20. The method of claim 19, wherein the second laser is a Bessel laser beam.

21. The method of claim 19, wherein the second laser is cast in a direction from the mother glass substrate to the mother substrate.

22. The method of claim 19, wherein the second laser is cast in a direction from the mother substrate to the mother glass substrate.

23. The method of claim 14, wherein the forming of the substrate, the forming of the cover window, and the forming of the welding part include:
cutting the mother substrate and the mother glass substrate along an outer edge of the preliminary welding part.

24. The method of claim 12, wherein the substrate includes a silicon wafer.

25. The method of claim 24, wherein the cover window includes glass.

26. The method of claim 25, wherein the welding part includes the silicon wafer of the substrate and the glass of the cover window.

27. The method of claim 12, further comprising:
forming a sealant surrounding at least one side surface of the welding part.
